(19) United States
(12) Patent Application Publication
(10) Pub. No.: US 2007/0278542 A1
(43) Pub. Date: Dec. 6, 2007

(54) Semiconductor device and fabricating method thereof

(75) Inventor: Koji Yuki, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/785,641

(22) Filed: Apr. 19, 2007

(30) Foreign Application Priority Data
Jun. 5, 2006 (JP) 2006-155675

(51) Int. Cl. H01L 23/482; H01L 29/768

(52) U.S. Cl. 257/288; 257/751; 257/E29.226; 257/E23.012

(57) ABSTRACT

There is provided a semiconductor device including: a semiconductor substrate including a supporting substrate, a first insulating film formed on the supporting substrate, and a silicon film having a first region and a second region formed on the first insulating film, and a third region at least a portion of which is disposed between the first region and the second region; a first diffusion layer formed on the first region of the silicon film and having a first conductive type; a second diffusion layer formed on the second region of the silicon film and containing impurities having a second conductive type, which has a polarity opposite to that of the first conductive type; a second insulating film formed on the third region of the silicon film; and a third insulating film formed on the second insulating film, as well as a method of fabricating the semiconductor device.

### CROSS-REFERENCE TO RELATED APPLICATION

This application claims priority under 35 USC 119 from Japanese Patent Application No. 2006-155675, the disclosure of which is incorporated by reference herein.

### BACKGROUND OF THE INVENTION

1. Field of the Invention

The present invention relates to a semiconductor device and a method for fabricating the device and, in particular, to a semiconductor device in which diffusion regions having opposite polarities are formed in a lateral direction on a surface of a substrate and a method for fabricating the device.

2. Description of the Related Art

A semiconductor diode formed on an SOI (Silicon On Insulator) substrate cannot have a configuration in which a junction direction of a PN junction formed in the substrate is in a depth direction of the substrate, as in a case where a bulk semiconductor substrate is used. In other words, the semiconductor diode on the SOI cannot have a configuration in which a p-type diffusion region (referred to as a “p diffusion region” hereinafter) and an N-type diffusion region (referred to as a “n diffusion region” hereinafter) can be disposed in an upper to lower direction of the substrate. Therefore, a semiconductor diode has generally been formed on the SOI so as to include a PN junction having a lateral junction direction (see, for example, Japanese Patent Application Laid-Open (JP-A) No. 7-335894 and JP-A No. 2001-28424).

However, when the diode in which the p diffusion region (anode) and the n diffusion region (cathode) form a junction in a lateral direction, it is necessary to form the p diffusion region and the n diffusion region having higher impurity densities so as to be arranged in a lateral direction at an active region in a silicon thin film on the SOI substrate. Further, a silicide film has necessarily been formed on each of the diffusion regions to obtain electrical connections with wirings such as contact plugs.

The diffusion regions and the silicide film are generally formed by utilizing a photolithography technique. However, in the step of using photolithography, alignment variation may occur. Therefore, it is necessary to design the diode with lager dimensions. This results in a problem such that the semiconductor device including the diode formed on the SOI substrate becomes larger.

### SUMMARY OF THE INVENTION

The present invention has been devised in consideration of the problems described above, and an object of this invention is to provide a semiconductor device including an SOI substrate which can be miniaturized and a method for fabricating the device.

In order to achieve the object described above, one aspect of the invention is to provide a semiconductor device comprising: a semiconductor substrate including a supporting substrate, a first insulating film formed on the supporting substrate, and a silicon film having a first region and a second region formed on the first insulating film, and a third region at least a portion of which is disposed between the first region and the second region; a first diffusion layer formed on the first region of the silicon film and having a first conductive type; a second diffusion layer formed on the second region of the silicon film and containing impurities having a second conductive type, which has a polarity opposite to that of the first conductive type; a second insulating film formed on the third region of the silicon film; and a third insulating film formed on the second insulating film.

Since the second insulating film is formed on a region between the first diffusion region and the second diffusion region, the second insulating film can be used as a mask at the time of forming the first diffusion region and the second diffusion region. Therefore, even when the semiconductor device is miniaturized, an exposure margin in a photolithography step for forming the first diffusion region and the second diffusion region can be adequately obtained. As a result, the semiconductor device can be miniaturized.

Another aspect of the invention is to provide a method of fabricating a semiconductor device, the method comprising: preparing a semiconductor substrate including a supporting substrate, a first insulating film formed on the supporting substrate, and a silicon film having a first region and a second region formed on the first insulating film, and a third region at least a portion of which is disposed between the first region and the second region; forming a second insulating film on a surface of the silicon film; forming a third insulating film on the second insulating film; etching the second and third insulating films to expose the first and the second regions in the silicon film; forming a first resist pattern on at least a portion of the third insulating film and on the second region; implanting impurities of a first conductive type in the first region by using the first resist pattern and the etched third insulating film as a mask to form a first diffusion layer in the first region; forming a second resist pattern on at least a portion of the third insulating film and on the first region; and implanting impurities of a second conductive type, which has a polarity opposite to that of the first conductive type, in the second region by using the second resist pattern and the third insulating film as a mask to form a second diffusion layer in the second region.

Since the second insulating film is formed on a region between the first diffusion region and the second diffusion region, the second insulating film can be used as a mask at the time of forming the first diffusion region and the second diffusion region. Therefore, even when the semiconductor device is miniaturized, an exposure margin in a photolithography step for forming the first diffusion region and the second diffusion region can be adequately obtained. As a result, the semiconductor device can be miniaturized.

Another aspect of the invention is to provide a method of fabricating a semiconductor device, the method comprising: preparing a semiconductor substrate including a supporting substrate, a first insulating film formed on the supporting substrate, and a silicon film having a first region and a second region formed on the first insulating film, and a third region at least a portion of which is disposed between the first region and the second region; forming a second insulating film on a surface of the silicon film; forming a third insulating film on the second insulating film; etching the second and third insulating film to expose the first and the second regions in the silicon film; implanting impurities of a first conductive type in the first and second regions by using the etched third insulating film as a mask; forming a fourth insulating film on the exposed silicon film and the third insulating film; etching back the fourth insulating film to form side walls at the side surfaces of the second and the third insulating films; forming a first resist pattern on at least a portion of the third insulating film and on the second region; implanting impurities of the first conductive type in the first region by using the first resist pattern, the etched third insulating film, and the side walls as a mask to form a first diffusion layer in a portion of the first region; forming a second resist pattern on at least a portion of the third insulating film and on the first region; and implanting impurities of a second conductive type, which has a polarity opposite to that of the first conductive type, in the second region by using the second resist pattern, and the etched third insulating film, and the side walls as a mask to form a second diffusion layer in a portion of the second region.

Since the second insulating film is formed on a region between the first diffusion region and the second diffusion region, the second insulating film can be used as a mask at the time of forming the first diffusion region and the second diffusion region. Therefore, even when the semiconductor device is miniaturized, an exposure margin in a photolithography step for forming the first diffusion region and the second diffusion region can be adequately obtained. As a result, the semiconductor device can be miniaturized.

Further, by forming the first diffusion region and second diffusion region by using the second insulating film, the side walls, which are formed at both sides of the first insulating film and the second insulating film, and the first/second resist pattern, as a mask, it is possible to control a distance between the first diffusion region and the second diffusion region by the width of the side walls. As a result, the withstand voltage of the semiconductor diode can be controlled. Further, by forming the region, which is dosed with impurities for adjusting the inversion threshold, below the side walls, it become possible to control the withstand voltage of the semiconductor device more effectively.

According to the present invention, it becomes possible to provide a semiconductor device including an SOI substrate which can be miniaturized and a method for fabricating the device.

### BRIEF DESCRIPTION OF THE DRAWINGS

Preferred exemplary embodiments of the present invention will be described in detail based on the following figures, wherein:

FIG. 1 is a plane view for illustrating a configuration of a semiconductor device of a first embodiment;

FIG. 2 is a plane view for illustrating a unit configuration of the semiconductor device of the first embodiment;

FIG. 3A is a process diagram for explaining the fabricating method of the semiconductor device of the first embodiment;

FIG. 3B is a process diagram for explaining the fabricating method of the semiconductor device of the first embodiment;

FIG. 3C is a process diagram for explaining the fabricating method of the semiconductor device of the first embodiment;

FIG. 3D is a process diagram for explaining the fabricating method of the semiconductor device of the first embodiment;

FIG. 3E is a process diagram for explaining the fabricating method of the semiconductor device of the first embodiment;

FIG. 3F is a process diagram for explaining the fabricating method of the semiconductor device of the first embodiment;

FIG. 4 is a plane view for illustrating another example of the semiconductor device of the first embodiment;

FIG. 5 is a plane view for illustrating a configuration of a semiconductor device of a second embodiment;

FIG. 6 is a plane view for illustrating a unit configuration of the semiconductor device of the second embodiment;

FIG. 7A is a process diagram for explaining the fabricating method of the semiconductor device of the second embodiment;

FIG. 7B is a process diagram for explaining the fabricating method of the semiconductor device of the second embodiment;

FIG. 7C is a process diagram for explaining the fabricating method of the semiconductor device of the second embodiment;

FIG. 7D is a process diagram for explaining the fabricating method of the semiconductor device of the second embodiment;

FIG. 7E is a process diagram for explaining the fabricating method of the semiconductor device of the second embodiment; and

FIG. 7F is a process diagram for explaining the fabricating method of the semiconductor device of the second embodiment.

### DETAILED DESCRIPTION OF THE INVENTION

Herebelow, embodiments of the invention will be described with reference to the drawings. However, forms, sizes and positional relationships of structural elements are no more than general illustrations such that the invention can be understood. Further, in the respective drawings, a portion of the hatching in cross sections is omitted to make the configuration clear. Moreover, while preferred structural examples of the present invention will be described below, compositions (materials), numerical conditions or the like of the structural elements are no more than preferred examples. Accordingly, the present invention is not to be limited to the embodiments described below.

### First Exemplary Embodiment

First, a first exemplary embodiment of the present invention will be described in detail with reference to the drawings.

In the invention according to the first embodiment, an insulating material and/or a gate electrode is used as a mask during photolithography processing. Due to this configuration, dimensional margins, which are necessary to obtain alignment precision at the time of forming diffusion regions (anode and cathode) and to align a contact plug to a silicide film precisely, can be decreased. Accordingly, an area in which a diode serving as a semiconductor device of the present invention is formed can be shrunk.

### (Configuration)

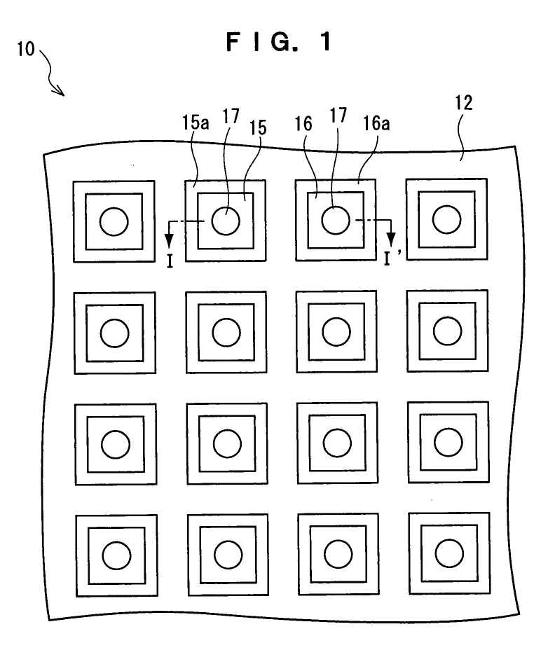

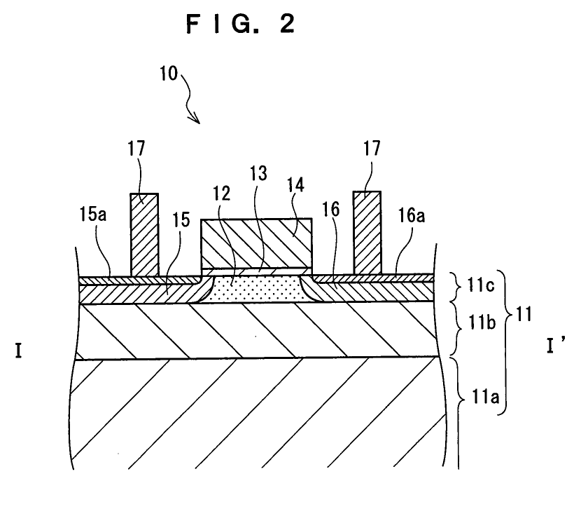

FIG. 1 is a plane view for illustrating a configuration of a semiconductor diode 10 of a first embodiment. Further, FIG. 2 is a plane view for illustrating a unit configuration of the semiconductor diode 10 of the first embodiment shown in FIG. 1. The semiconductor diode 10 of the first embodiment is structured by combining one or more units of elements. It should be noted that a gate oxide film 13 and a mask insulating film 14 are omitted in FIG. 1 for simplicity. Further, an interlayer insulating film is omitted in FIG. 2 for simplicity.

The semiconductor diode 10 according to the first embodiment has a configuration in which a p+ diffusion region 15 and an n+ diffusion region 16 are arranged at a regular pitch alternately in both of longitudinal and lateral directions. Due to this configuration, areas at which the p+ diffusion region 15 and the n+ diffusion region 16 oppose to each other in the semiconductor diode 10 can be increased. As a result, the driving capability of the semiconductor diode can be improved. Further, a region 12 (referred to as a “carrier region” hereinafter), through which carriers flow when the semiconductor diode 10 is active, is formed between the p+ diffusion 15 and the n+ diffusion region 16.

Further, as seen in FIGS. 1 and 2, the unit configuration of the semiconductor diode 10 is formed of an SOI substrate 11 including: a supporting substrate 11a; a buried oxide 11b formed on the supporting substrate 11a; and a silicon thin film 11c formed on the buried oxide 11b. As the supporting substrate 11a, a silicon substrate may be used. As the buried oxide film 11b, a silicon oxide film may be used. A thickness of the supporting substrate 11a is preferably set to be about 145 nm (nanometers), and a thickness of the silicon thin film 11c is preferably set to be about 50 nm.

The silicon thin film 11c composing the SOI substrate 11 is divided into an element-forming region (so-called “active region”) and an element-isolating region (so-called “field region”). This element-isolating region can be formed by utilizing a LOCOS (Local Oxidation of Silicon) technique, STI (Shallow Trench Isolation) technique or the like.

An inversion threshold of the active region in the silicon thin film 11c is adjusted by doping impurities, which have, for example, an n-type conductivity, (phosphorus ions or the like) with a relatively lower concentration (than an impurity concentration of the n+ diffusion region 16 described later).

On a portion of the active region in the silicon thin film 11c (referred to as a “third region” hereinafter), the gate oxide film 13 is formed. The gate oxide film 13 can be formed, for example, by a thermal oxidation technique. A thickness of the gate oxide film 13 may be set to about 5 nm.

On the gate oxide film 13, a mask insulating film 14 is formed. The mask insulating film 14 is a mask for defining regions at which the impurities are implanted at the time of forming a p-type high concentration diffusion region described later (referred to as a “p+ diffusion region” hereinafter) and at the time of forming an n-type high concentration diffusion region (referred to as a “n+ diffusion region” hereinafter). The mask insulating film 14 can be formed of silicon oxide film or the like. Further, a thickness of the mask insulating film 14 may be set to about 100 nm, such that the impurities implanted do not reach to the silicon thin film 11c.

At a pair of regions at both sides of the mask insulating film 14 and the gate oxide film 13 on the active region of the silicon thin film 11c (referred to as a “first region” and a “second region” hereinafter), the p+ diffusion region 15 and n+ diffusion region 16 are formed, respectively. The p+ diffusion region 15 is formed by doping the silicon thin film 11c with As ions, B ions or the like. Here, the impurity concentration may be set to about 1×10¹⁸/nm³. On the other hand, the n+ diffusion region 16 is formed by doping the silicon thin film 11c with P ions or the like. Here, the impurity concentration may be set to about 1×10¹⁸/nm³. It should be noted that the p+ diffusion region 15 and the n+ diffusion region 16 are formed so as to extend to regions in the silicon thin film 11c below the mask insulating film 14. Further, it should be noted that the region between the p+ diffusion region 15 and the n+ diffusion region 16 functions as a carrier region 12.

At respective surfaces of the p+ diffusion region 15 and the n+ diffusion region 16, a silicide film 15a and a silicide film 16a are formed to make the resistance of the regions lower.

The SOI substrate 11, on which the above described semiconductor diode 10 is formed, is covered by an unillustrated interlayer insulating film. Then, contact holes are formed in the interlayer insulating film to expose both of the silicide film 15a on the p+ diffusion region 15 and the silicide film 16a on the n+ diffusion region 16, respectively. In the contact holes, contact plugs 17 are formed.

### (Fabricating Method)

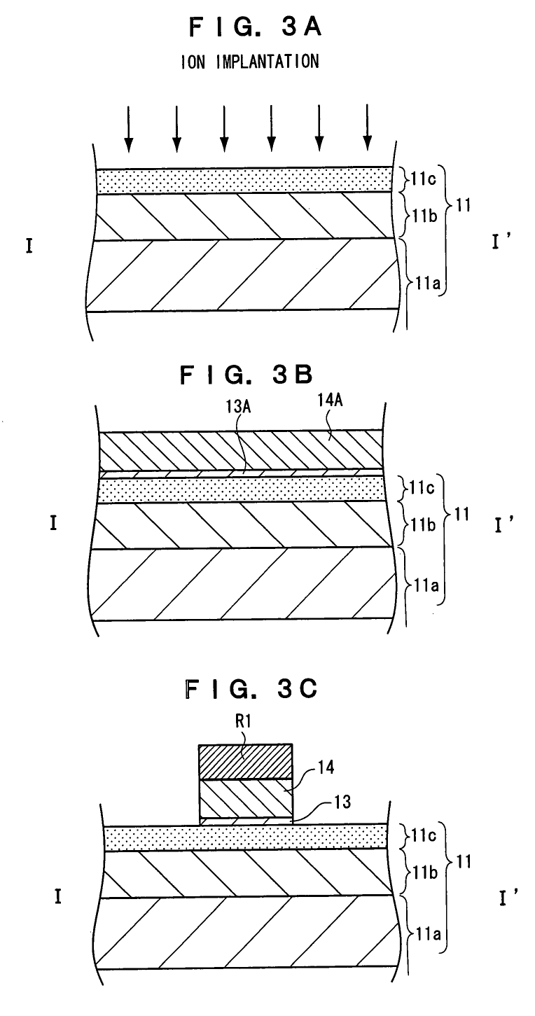

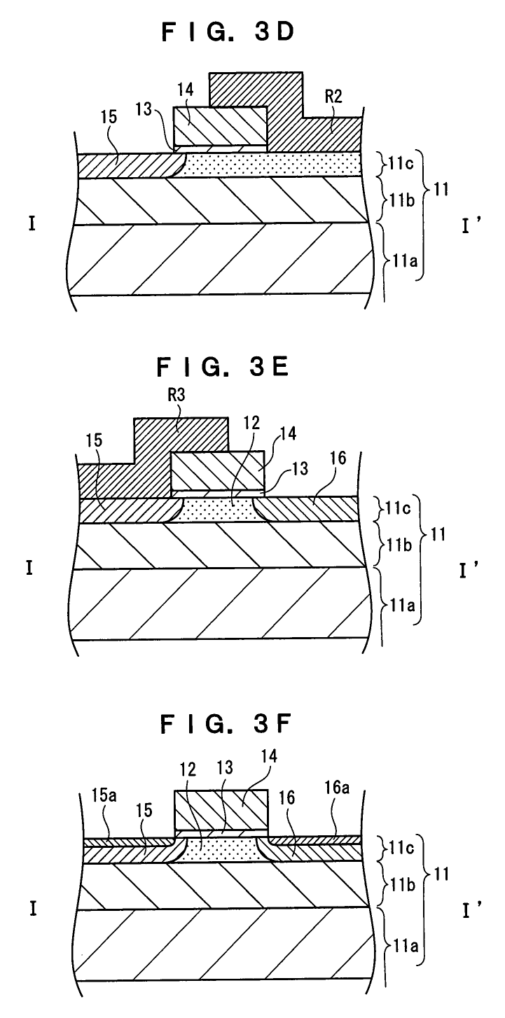

Next, a method for fabricating the semiconductor diode 10 according to the present embodiment will be described in detail with respect to the drawings. Each of FIGS. 3A-3F is a process diagram for illustrating the fabricating method of the semiconductor diode 10 of the present embodiment.

In the present method, first, an SOI substrate 11 including a supporting substrate 11a, a buried oxide film 11b and a silicon thin film 11c is prepared. Then, unillustrated element-isolation regions are formed by using the LOCOS technique or the STI technique in the silicon thin film 11c. These element-isolation regions define one or more active regions on the silicon thin film 11c.

Then, as seen in FIG. 3A, the inversion threshold of the active regions in the silicon thin film 11c is adjusted by doping n-type impurities such as P ions therein. The dose of the impurities may be set to about 1×10¹³/cm³.

Next, a silicon oxide film 13A having a thickness of about 5 nm is formed by thermally oxidizing the surface of the silicon thin film 11c. Here, conditions of the thermal oxidation may be set to a temperature of 850 degrees C. and a time of 30 minutes. Then, an insulating film 14A having a thickness of about 100 nm is formed on the silicon oxide film 13A by depositing insulating material such as silicon oxide or silicon nitride with a CVD (Chemical Vapor Deposition) technique. At this point in time, as seen in FIG. 3B, the silicon oxide film 13A and the insulating film 14A are formed on the SOI substrate 11.

Next, a (photo) resist pattern R1 which includes openings in a lattice pattern (see FIG. 1) is formed by a conventional photolithography technique. Then, the insulating film 14A and the silicon oxide film 13A are etched in this order by using the resist pattern R1 as an etching mask. As a result, for example, as seen in FIG. 3C, on portions of the silicon thin film 11c, a gate oxide film 13 having a thickness of 5 nm and a mask insulating film 14 having a thickness of 100 nm are formed.

Next, after the resist pattern R1 is removed, a resist pattern R2 having openings at least on the regions on which the p+ diffusion region 15 is formed by using the conventional photolithography technique. At this time, edges of the resist pattern R2 (i.e., edges of the openings) are positioned on the mask insulating film 14. Due to this positioning, during ion-implantation for forming the p+ diffusion region 15, the mask insulating film 14 other than the resist pattern R2 functions as a mask. Therefore, the resist pattern R2 should cover at least regions on the silicon thin film 11c at which the n+ diffusion region 16 is formed. In other words, a margin corresponding to width of the mask insulating film 14 at the time of forming the resist pattern R2 is obtained. Next, p-type impurities such as As ions or B ions are implanted to the active regions in the silicon thin film 11c, which are exposed, by using the resist pattern R2 and the mask insulating film 14 as a mask. At this time, as seen in FIG. 3D, at portions of the active regions in the silicon thin film 11c, the p+ diffusion region 15 is formed. Here, the dose of the ion-implantation may be set to about 1×10¹⁵/nm².

Next, after the resist pattern R2 is removed, a resist pattern R3 having openings at least on the regions on which the n+ diffusion region 16 is formed by using the conventional photolithography technique. At this time, edges of the resist pattern R3 (i.e., edges of the openings) are positioned on the mask insulating film 14 similarly to the resist pattern R2. Due to this positioning, during ion-implantation for forming the n+ diffusion region 16, the mask insulating film 14 other than the resist pattern R3 functions as a mask. Therefore, the resist pattern R3 should cover at least regions on the silicon thin film 11c at which the n+ diffusion region 16 is formed. In other words, a margin corresponding to width of the mask insulating film 14 at the time of forming the resist pattern R3 is obtained. Next, n-type impurities such as P ions are implanted to the active regions in the silicon thin film 11c, which are exposed, by using the resist pattern R3 and the mask insulating film 14 as a mask. At this time, as seen in FIG. 3E, at portions of the active regions in the silicon thin film 11c, the n+ diffusion region 16 is formed. Here, the dose of the ion-implantation may be set to about 1×10¹⁵/nm².

Then, after removing the resist pattern R3, surfaces of the p+ diffusion region 15 and the n+ diffusion region 16 are silicided. Accordingly, as seen in FIG. 3F, a silicide film 15a and a silicide film 16a are formed on the regions, respectively.

After that, an interlayer insulating film is formed so as to cover the diode structure fabricated in accordance with the above steps. In the interlayer insulating film, contact plugs 17 for electrically connecting respectively to the silicide film 15a on the p+ diffusion region and the silicide film 16a on the n+ diffusion region 16 are formed. As a result, the semiconductor diode 10 of the present embodiment such as shown in FIGS. 1 and 2 is achieved.

### (Effects)

As described above, the semiconductor diode 10 of the present embodiment includes: an SOI substrate 11 comprising a supporting substrate 11a, a buried oxide film 11b formed on the supporting substrate 11a, a silicon film 11c having a first region and a second region formed on the buried oxide film 11b, and a third region at least a portion of which is disposed between the first region and the second region; a p+ diffusion region 15 (first diffusion layer) formed on the first region of the silicon film 11c and having p-type impurities (first conductive type); a n+ diffusion region 16 (second diffusion layer) formed on the second region of the silicon film 11c and having n-type impurities (second conductive type), which has a polarity opposite to that of the p-type; a gate oxide 13 (second insulating film) formed on the third region of the silicon film 11c; and a mask insulating film 14 (third insulating film) formed on the gate oxide film 13.

Since the mask insulating film 14 is formed on a region between the region to be the p+ diffusion region 15 and the region to be the n+ diffusion region 16, the mask insulating film 14 can be used as a mask at the time of forming the p+ diffusion region 15 and the n+ diffusion region 16. Therefore, even when the semiconductor diode 10 is miniaturized, an exposure margin in the photolithography steps for forming the p+ diffusion region 15 and the n+ diffusion region 16 can be adequately obtained. As a result, the semiconductor diode 10 can be miniaturized.

Further, the method for fabricating the semiconductor diode 10 of the present embodiment includes: preparing an SOI substrate 11 comprising a supporting substrate 11a, a buried oxide film 11b (first oxide film) formed on the supporting substrate 11a, a silicon film 11c having a first second and a second region formed on the buried oxide film 11b, and a third region at least a portion of which is disposed between the first region and the second region; forming, on the silicon film 11c, a silicon oxide film 13A (second insulating film) to be processed to a gate oxide film 13 on the silicon film 11c; forming, on the silicon oxide film 13A, an insulating film 14A (third insulating film) to be processed to a mask insulating film 14; etching the silicon oxide film 13A and the insulating film 14A to expose a first region and a second region in the silicon film 11c and to form the gate oxide film 13 and the mask insulating film 14; forming, on at least a portion of the mask oxide film 14 (third insulating film) and on the second region, a first resist pattern R2; implanting p-type (first conductive type) impurities to the first region, by using both of the first resist pattern R2 and the mask oxide film 14 as a mask, to form a p+ diffusion region 15 (first diffusion layer) in the first region; forming, on at least a portion of the mask oxide film 14 and on the first region, a second resist pattern R3; and implanting n-type (second conductive type) impurities, which have a polarity opposite to that of the p-type, to the second region, by using both of the second resist pattern R3 and the mask oxide film 14 as a mask, to form a n+ diffusion region 16 (second diffusion layer) in the second region.

Since the mask insulating film 14 is formed on a region between the region to be the p+ diffusion region 15 and the region to be the n+ diffusion region 16, the mask insulating film 14 can be used as a mask at the time of forming the p+ diffusion region 15 and the n+ diffusion region 16. Therefore, even when the semiconductor diode 10 is miniaturized, an exposure margin in the photolithography steps for forming the p+ diffusion region 15 and the n+ diffusion region 16 can be adequately obtained. As a result, the semiconductor diode 10 can be miniaturized.

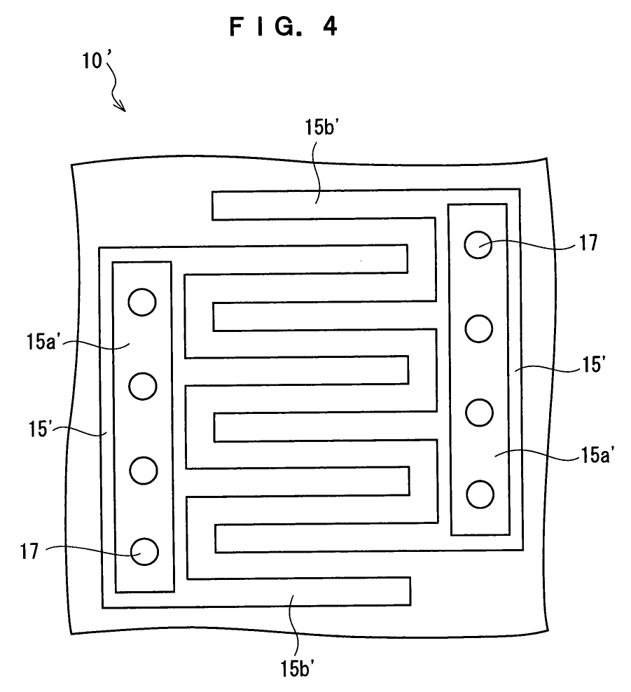

In the above description, a configuration in which the p+ diffusion regions 15 and the n+ diffusion regions 16 are two-dimensionally arranged in a lattice pattern has been described. However, the present invention is not limited to this configuration. For example, as seen in FIG. 4, a pectinate configuration, in which a p+ diffusion region 15′ and an n+ diffusion region 16′ include protruding portions (so-called “fingers”) 15b′ and 16b′, respectively, can be used. Due to this configuration, areas at which the p+ diffusion region 15′ and the n+ diffusion region 16′ oppose each other in the semiconductor diode 10 can be increased, similarly to the configuration described above with respect to FIGS. 1 and 2. Here, it is should be noted that the silicide film 15a′ and the silicide film 16a′ can be formed at regions other than the protruding portions 15b′ and 16b′.

Further, in the present embodiment, the mask insulating film 14 is used as a mask at the time of ion-implantation. However, the present invention is not limited to this. It is possible to employ a configuration in which a gate electrode is formed by polysilicon film including impurities on the gate oxide film 13 and ion-implantation is conducted by using the gate electrode as a mask to form the p+ diffusion region 15 and the n+ diffusion region 16.

Moreover, the semiconductor diode 10 of the present embodiment can be used, for example, as a protection circuit to improve ESD (Electro Static Discharge) characteristics. However, the present invention is not limited to this and can be applied to a various kind of parts.

### Second Exemplary Embodiment

Next, a second exemplary embodiment of the present invention is described in detail with respect to the drawings. In the following explanation, the same elements in the first embodiment are denoted by the same numerals and the detailed explanation thereof is omitted. Further, a configuration, which is not described, is as same as that of the first embodiment.

In the invention of the second embodiment, as in the first embodiment, an insulating material and/or a gate electrode is used as a mask during photolithography processing. Due to this configuration, dimensional margins, which is necessary to obtain alignment precision at the time of forming diffusion regions (anode and cathode) and to align a contact plus to a silicide film precisely, can be decreased. Accordingly, and area in which a diode of the present invention is formed can be shrunk.

### (Configuration)

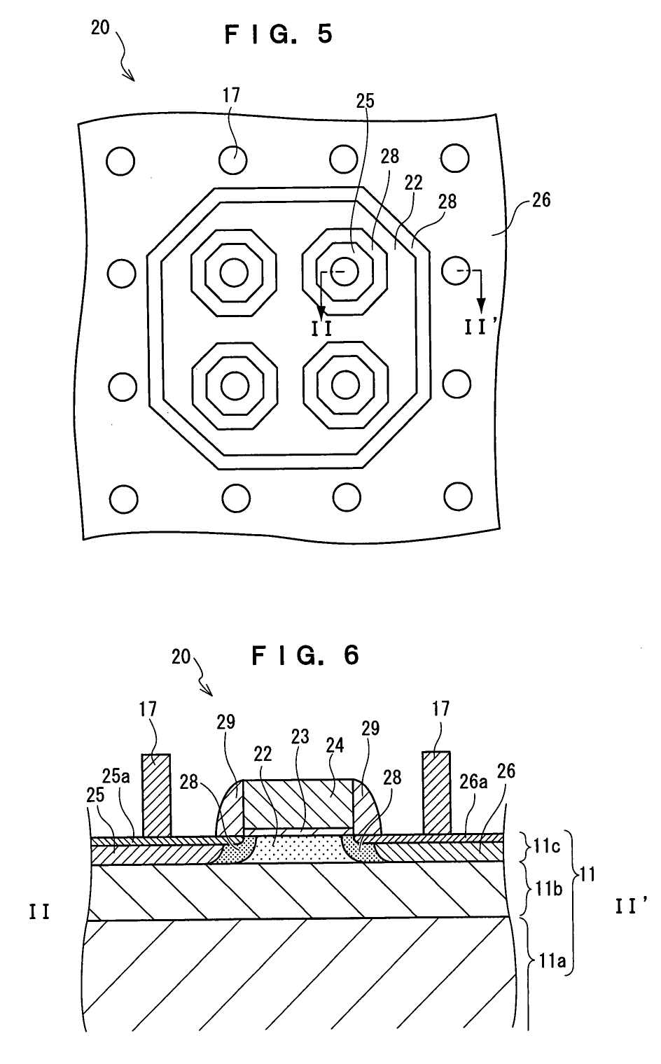

FIG. 5 is a plane view for illustrating a configuration of a semiconductor diode 20 of a second embodiment. Further, FIG. 6 is a plane view for illustrating a unit configuration of the semiconductor diode 20 of the first embodiment shown in FIG. 5. The semiconductor diode 20 of the second embodiment is structured by combining one or more units of elements. It should be noted that a gate oxide film 23 and a mask insulating film 24 are omitted in FIG. 5 for simplicity. Further, an interlayer insulating film is omitted in FIG. 6 for simplicity.

The semiconductor diode 20 according to the second embodiment has a configuration in which an n+ diffusion region 26 is formed so as to enclose plural p+ diffusion regions 25 as seen in FIG. 5. Due to this configuration, areas at which the p+ diffusion regions 25 and the n+ diffusion region 26 oppose to each other in the semiconductor diode 20 can be increased. As a result, the driving capability of the semiconductor diode can be improved.

Further, a region 22 (“carrier region” hereinafter), through which carriers flow when the semiconductor diode 20 is active, and an n-type low concentration diffusion region 28 (“n− diffusion region” hereinafter) enclosing the carrier region 22 are formed between the p+ diffusions 25 and the n+ diffusion region 26.

The impurity concentration of the n− diffusion region 28 is, for example, higher than that of the carrier region 22 and lower than that of the n+ diffusion region 26. The n− diffusion region 28 is provided in order to adjust the threshold voltage of the semiconductor diode 20 to easily control the withstand voltage characteristics of the semiconductor diode 20.

Further, as seen in FIGS. 5 and 6, the unit configuration of the semiconductor diode 20 is formed of an SOI substrate 11 including: a supporting substrate 11a; a buried oxide 11b formed on the supporting substrate 11a; and a silicon thin film 11c formed on the buried oxide 11b, as in the first embodiment.

The silicon thin film 11c composing the SOI substrate 11 is divided into an element-forming region (so-called “active region”) and an element-isolating region (so-called “field region”) by forming an unillustrated element isolation film, as in the first embodiment. Further, an inversion threshold of the active region in the silicon thin film 11c is adjusted by doping impurities, which is, for example, n-type, (P ions or the like) with a relatively lower concentration (than impurity concentration of the n+ diffusion region 26 described later), as in the first embodiment.

On a portion of the active region in the silicon thin film 11c, a gate oxide film 23 is formed. The gate oxide film 23 can be formed, for example, by thermal oxidation. A thickness of the gate oxide film 23 may be set to about 5 nm.

On the gate oxide film 23, a mask insulating film 24 is formed. The mask insulating film 24 is a mask for defining regions at which the impurities are implanted at the time of forming a p+ diffusion region 25 and at the time of forming an n+ diffusion region 26. The mask insulating film 24 can be formed of silicon oxide film or the like. Further, a thickness of the mask insulating film 24 may be set to about 100 nm, when the impurities implanted do not reach to the silicon thin film 11c.

At both sides of the mask insulating film 24 and the gate oxide film 23 on the active region of the silicon thin film 11c, side walls 29 are formed, respectively. The side walls 29 can be formed of silicon nitride film or the like. A thickness of the side walls 29 in a lateral direction may be set to 100 nm or the like.

At the active region in the silicon thin film 11c, under the side walls 29, the n− diffusion region 28 is formed. The n− diffusion region 28 is a region to adjust the threshold voltage of the semiconductor diode 20, as described above. The n− diffusion region 28 can be formed by doping the silicon thin film 11c with P ions or the like. Further, the impurity concentration of the n− diffusion region 28 may be set to about 1×10¹⁷/cm³. Here, a region in the active region between the n− diffusion regions 28 functions as the carrier region 22.

At both sides of the mask insulating film 24 and the gate oxide film 23, and at a pair of regions under the side walls 29 on the active region of the silicon thin film 11c (referred to a “first region” and a “second region” hereinafter), the p+ diffusion region 25 and n+ diffusion region 26 are formed, respectively. The p+ diffusion region 25 is formed by doping the silicon thin film 11c with As ions, B ions or the like. Here, the impurity concentration may be set to about 1×10¹⁸/nm³. On the other hand, the n+ diffusion region 26 is formed by doping the silicon thin film 11c with P ions or the like. Here, the impurity concentration may be set to about 1×10¹⁸/nm³. It should be noted that the p+ diffusion region 25 and the n+ diffusion region 26 are formed so as to extend to regions in the silicon thin film 11c below the side walls 29.

In respective surfaces of the p+ diffusion region 25 and the n+ diffusion region 26, a silicide film 25a and a silicide film 26a are formed to make the resistance of the regions lower.

The SOI substrate 11, on which the above described semiconductor diode 20 is formed, is covered by an unillustrated interlayer insulating film. Then, contact holes are formed in the interlayer insulating film to expose both of the silicide film 25a on the p+ diffusion region 25 and the silicide film 26a on the n+ diffusion region 26, respectively. In the contact holes, contact plugs 17 are formed.

### (Fabricating Method)

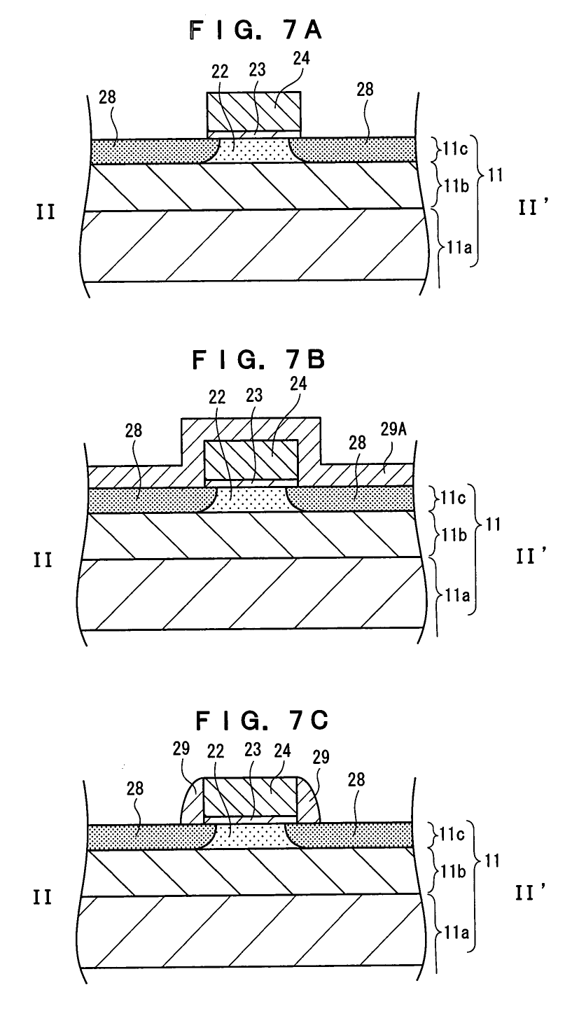

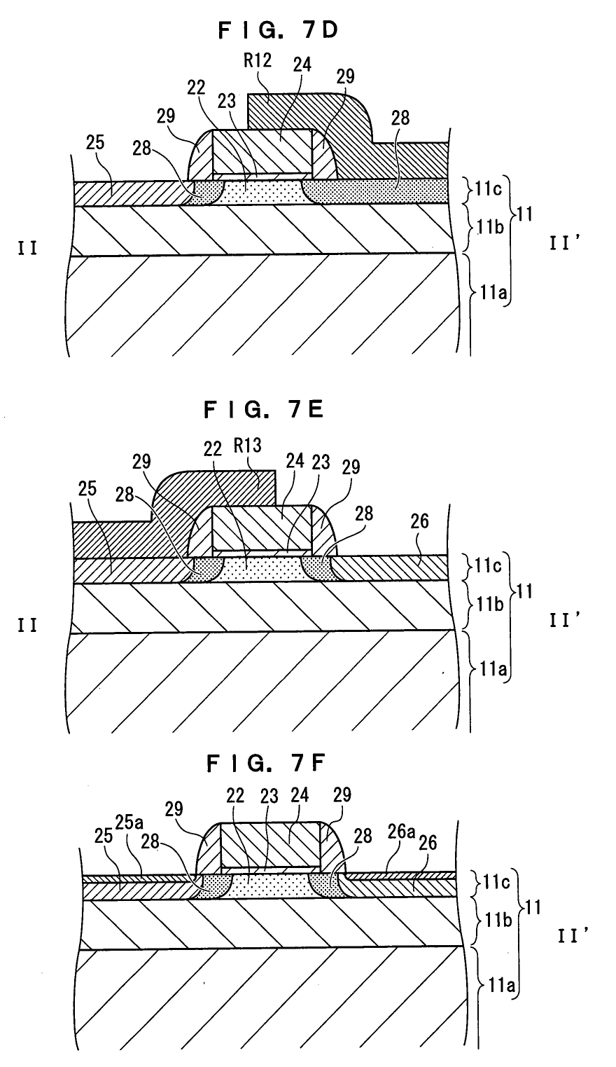

Next, a method for fabricating the semiconductor diode 20 according to the present embodiment will be described in detail with respect to the drawings. Each of FIGS. 7A-7F illustrates a process diagram for fabricating the semiconductor diode 20 of the present embodiment. Processes as same as in the first embodiment are omitted to be described in detail.

In the present method, first, an SOI substrate 11 including a supporting substrate 11a, a buried oxide film 11b and a silicon thin film 11c is prepared, as in the first embodiment. Then, element-isolation regions are formed by using the LOCOS technique or the STI technique in the silicon thin film 11c. These element element-isolation regions define one or more active regions on the silicon thin film 11c.

Then, as described with respect to FIG. 3A, the inversion threshold of the active regions in the silicon thin film 11c is adjusted by doping n-type impurities such as P ions therein. The dose of the impurities may be set to about 1×10¹³/cm³.

Next, a silicon oxide film 13A having a thickness of about 5 nm is formed by thermally oxidizing the surface of the silicon thin film 11c. Here, conditions of the thermal oxidation may be set to temperature of 850 degree C. and time of 30 minutes. Then, an insulating film 14A having a thickness of about 100 nm is formed on the silicon oxide film 13A by depositing insulating material such as silicon oxide and silicon nitride with CVD (Chemical Vapor Deposition) technique. At this point of time, as described with respect to FIG. 3B, the silicon oxide film 13A and the insulating film 14A are formed on the SOI substrate 11.

Next, a (photo) resist pattern which includes openings as same as the p+ diffusion region 25 and the n+ diffusion region 26 is formed by a conventional photolithography technique. Then, the insulating film 14A and the silicon oxide film 13A are etched in this order by using the resist pattern as an etching mask. Here, as described with respect to FIG. 3C, on portions of the silicon thin film 11c, a gate oxide film 13 having a thickness of 5 nm and a mask insulating film 24 having a thickness of 100 nm are formed.

Next, n-type impurities such as P ions are implanted to the active regions in the silicon thin film 11c, which is exposed, by using the mask insulating film 24 as a mask. At this time, as seen in FIG. 7A, at portions of the active regions in the silicon thin film 11c, a pair of n+ diffusion regions 28 is formed. Here, dose of the ion-implantation may be set to about 1×10¹⁴/nm².

Next, after removing the resist pattern on the mask insulating film 24, as seen in FIG. 7B, an insulating film 29A having a thickness of about 100 nm is formed on entire of the SOI substrate 11 by depositing insulating material by CVD or the like. It is preferable to use such an insulating material that shows that an adequate selectivity to the silicon thin film 11c and the mask insulating film 24 during etching as the insulating material to be deposited, for example, a silicon nitride when the mask insulating film 24 is formed of silicon oxide film, as the insulating material to be deposited.

Next, the insulating film 29A on the SOI substrate 11 is etched back to form the side walls 29 at both sides of the gate oxide film 23 and the mask insulating film 24 as seen in FIG. 7C.

Next, a resist pattern R12 having openings at least on the regions on which the p+ diffusion region 25 is formed by using the conventional photolithography technique. At this time, edges of the resist pattern R12 (i.e., edges of the openings) is positioned on the mask insulating film 24. Due to this positioning, during ion-implantation for forming the p+ diffusion region 25, the mask insulating film 24 other than the resist pattern R12 functions as a mask. Therefore, the resist pattern R12 should cover at least regions on the silicon thin film 11c at which the n+ diffusion region 26 is formed. In other words, a margin corresponding to width of the mask insulating film 24 at the time of forming the resist R12 is obtained. Next, p-type impurities such as As ions or B ions are implanted to the active regions in the silicon thin film 11c, which is exposed, by using the resist pattern R12 and the mask insulating film 24 as a mask. At this time, as seen in FIG. 7D, at portions of the active regions in the silicon thin film 11c, the p+ diffusion region 25 is formed. Here, dose of the ion-implantation may be set to about 1×10¹⁵/nm².

Next, after the resist pattern R12 is removed, a resist pattern R13 having openings at least on the regions on which the n+ diffusion region 26 is formed by using the conventional photolithography technique. At this time, edges of the resist pattern R13 (i.e., edges of the openings) is positioned on the mask insulating film 24 as the resist R12. Due to this positioning, during ion-implantation for forming the n+ diffusion region 26, the mask insulating film 24 other than the resist pattern R13 functions as a mask. Therefore, the resist pattern R13 should cover at least regions on the silicon thin film 11c at which the n+ diffusion region 26 is formed. In other words, a margin corresponding to width of the mask insulating film 24 at the time of forming the resist R13 is obtained. Next, n-type impurities such as P ions are implanted to the active regions in the silicon thin film 11c, which is exposed, by using the resist pattern R13 and the mask insulating film 24 as a mask. At this time, as seen in FIG. 7E, at portions of the active regions in the silicon thin film 11c, the n+ diffusion region 26 is formed. Here, dose of the ion-implantation may be set to about 1×10¹⁵/nm².

Then, after removing the resist pattern R13, surfaces of the p+ diffusion region 25 and the n+ diffusion region 26 are silicided. Accordingly, as seen in FIG. 7F, a silicide film 25a and a silicide film 26a are formed on the regions, respectively.

After that, an interlayer insulating film is formed so as to cover the diode structure fabricated in accordance with the above steps. In the interlayer insulating film, contact plugs 17 for electrically connecting respectively to the silicide film 25a on the p+ diffusion region and the silicide film 26a on the n+ diffusion region 26. As a result, as seen in FIGS. 5 and 6, the semiconductor diode 20 of the present embodiment is achieved.

### (Effects)

As described above, the semiconductor diode 20 of the present embodiment includes: an SOI substrate 11 comprising a supporting substrate 11a, a buried oxide film 11b formed on the supporting substrate 11a, a silicon film 11c having a first second and a second region formed on the buried oxide film 11b, and a third region at least a portion of which is disposed between the first region and the second region; a p+ diffusion region 25 (first diffusion layer) formed on the first region of the silicon film 11c and having p-type impurities (first conductive type); a n+ diffusion region 26 (second diffusion layer) formed on the second region of the silicon film 11c and having n-type impurities (second conductive type), which is opposite polarity of to the p-type; a gate oxide 23 (second insulating film) formed on the third region of the silicon film 11c; and a mask insulating film 24 (third insulating film) formed on the gate oxide film 23.

Further, the semiconductor diode 20 of the present embodiment includes the side walls 29 formed at the sides of the gate oxide film 23 and the mask insulating film 24, and the n− diffusion region 28 formed below the side walls 29 in the silicon thin film 11c.

Since the mask insulating film 14 is formed on a region between the region to be p+ diffusion region 25 and the region to be n+ diffusion region 26, the mask insulating film 24 can be used as a mask at the time of forming the p+ diffusion region 25 and the n+ diffusion region 26. Therefore, even when the semiconductor diode 20 is miniaturized, an exposure margin in photolithography step for forming the p+ diffusion region 25 and the n+ diffusion region 26 can be adequately obtained. As a result, the semiconductor diode 20 can be miniaturized.

Further, by forming the p+ diffusion region 25 and n+ diffusion region 26 by using the mask insulating film 24, the side walls 29, which is formed at both sides of the gate oxide film 23 and the mask insulating film 24, and the resist pattern R12/R13, it can be possible to control a distance between the p+ diffusion region 25 and the n+ diffusion region 26 by width of the side walls. As a result, the withstand voltage of the semiconductor diode 20 can be controlled. Further. By forming the n− region, which is dosed with impurities for adjusting the inversion threshold, below the side walls, it become possible to control the withstand voltage of the semiconductor diode 20 more effectively.

Further, the method for fabricating the semiconductor diode 20 of the present embodiment includes: preparing an SOI substrate 11 comprising a supporting substrate 11a, a buried oxide film 11b (first oxide film) formed on the supporting substrate 11a, a silicon film 11c having a first second and a second region formed on the buried oxide film 11b, and a third region at least a portion of which is disposed between the first region and the second region; forming, on the silicon film 11c, a silicon oxide film 13A (second insulating film) on the silicon film 11c; forming, on the silicon oxide film 13A, an insulating film 14A (third insulating film): etching the second insulating film and the third insulating film to form a gate oxide film 23 and a mask insulating film 24 and to expose a first region and a second region in the silicon film 11c; implanting p-type (first conductive type) impurities to the first region and the second region, by using both of the mask insulating film 24 as a mask; forming, on the exposed silicon film 11c and the mask insulating film 24, an insulating film 29A (fourth insulating film); etching back the insulating film 29A to form side walls 29 at the sides of the gate oxide film 23 and the mask insulating film 24; forming, on at least a portion of the mask oxide film 24 and on the second region, a first resist pattern R12; forming a p+ diffusion region 25 (first diffusion layer) at a portion of the first region by implanting p-type impurities to the first region by using the first resist pattern R12, the mask insulating film 24 and the side walls 29 as a mask; forming, on at least a portion of the mask oxide film 24 and on the first region, a second resist pattern R13; and implanting n-type (second conductive type) impurities to the second region, by using both of the second resist pattern R13, the mask oxide film 24 and the side walls 29 as a mask, to form a n+ diffusion region 26 (second diffusion layer) in a portion of the second region.

Since the mask insulating film 24 is formed on a region between the region to be p+ diffusion region 25 and the region to be n+ diffusion region 26, the mask insulating film 24 can be used as a mask at the time of forming the p+ diffusion region 25 and the n+ diffusion region 26. Therefore, even when the semiconductor diode 20 is miniaturized, an exposure margin in photolithography step for forming the p+ diffusion region 25 and the n+ diffusion region 26 can be adequately obtained. As a result, the semiconductor diode 10 can be miniaturized. Further, by forming the p+ diffusion region 25 and n+ diffusion region 26 by using the mask insulating film 24, the side walls 29, which is formed at both sides of the gate oxide film 23 and the mask insulating film 24, and the resist pattern R12/R13, it can be possible to control a distance between the p+ diffusion region 25 and the n+ diffusion region 26 by width of the side walls. As a result, the withstand voltage of the semiconductor diode 20 can be controlled. Further. By forming the n− region, which is dosed with impurities for adjusting the inversion threshold, below the side walls, it become possible to control the withstand voltage of the semiconductor diode 20 more effectively.

It should be note that the p+ diffusion region 25 and the n+ diffusion region 26 in the present embodiment are not limited to the configuration. Another configuration such as the lattice configuration as in the first embodiment and the pectinate configuration can be employed. Due to these configurations, areas at which the p+ diffusion region and the n+ diffusion region oppose to each other can be increased as in the first embodiment.

Further, in the present embodiment, the mask insulating film 24, or both of the mask insulating mask 24 and the side walls 29 are used as a mask at the time of the ion-implantation. However, the present invention is not limited to this configuration. A configuration, in which a gate electrode of polysilicon film including impurities is formed, and the n− diffusion region 28, the p+ diffusion region 25 and the n+ diffusion region 26 are respectively formed by using the gate electrode or both of the gate electrode and the side walls 29, can be used.

Moreover, the semiconductor diode 20 of the present embodiment can be used, for example, as a protection circuit to improve ESD (Electro Static Discharge) characteristics. However, the present invention is not limited to this and can be applied to a various kind of parts.

Further, the first embodiment and the second embodiment described above are only examples and other variations can be made.

In particular, present invention may include various methods of fabricating a semiconductor device as below.

According to an aspect of the present invention, there is provided a method of fabricating a semiconductor device, the method comprising:

preparing a semiconductor substrate including a supporting substrate, a first insulating film formed on the supporting substrate, and a silicon film having a first region and a second region formed on the first insulating film, and a third region at least a portion of which is disposed between the first region and the second region;
forming a second insulating film on a surface of the silicon film;
forming a third insulating film on the second insulating film;
etching the second and third insulating films to expose the first and the second regions in the silicon film;
forming a first resist pattern on at least a portion of the third insulating film and on the second region;
implanting impurities of a first conductive type in the first region by using the first resist pattern and the etched third insulating film as a mask to form a first diffusion layer in the first region;
forming a second resist pattern on at least a portion of the third insulating film and on the first region; and
implanting impurities of a second conductive type, which has a polarity opposite to that of the first conductive type, in the second region by using the second resist pattern and the third insulating film as a mask to form a second diffusion layer in the second region.

According to another aspect of the present invention, there is provide a method of fabricating a semiconductor device, the method comprising:

preparing a semiconductor substrate including a supporting substrate, a first insulating film formed on the supporting substrate, and a silicon film having a first region and a second region formed on the first insulating film, and a third region at least a portion of which is disposed between the first region and the second region;
forming a second insulating film on a surface of the silicon film;
forming a third insulating film on the second insulating film;
etching the second and third insulating film to expose the first and the second regions in the silicon film;
implanting impurities of a first conductive type in the first and second regions by using the etched third insulating film as a mask;
forming a fourth insulating film on the exposed silicon film and the third insulating film;
etching back the fourth insulating film to form side walls at the side surfaces of the second and the third insulating films;
forming a first resist pattern on at least a portion of the third insulating film and on the second region;
implanting impurities of the first conductive type in the first region by using the first resist pattern, the etched third insulating film, and the side walls as a mask to form a first diffusion layer in a portion of the first region;
forming a second resist pattern on at least a portion of the third insulating film and on the first region; and
implanting impurities of a second conductive type, which has a polarity opposite to that of the first conductive type, in the second region by using the second resist pattern, and the etched third insulating film, and the side walls as a mask to form a second diffusion layer in a portion of the second region.

Further, in the above aspects, the third region may be provided in a lattice form so as to enclose each periphery of the first region and the second region, and the first diffusion layer and the second diffusion layer are plurally arranged so as to neighbor to each other via the third region.

In addition, in the above aspects, the first diffusion layer may include plural first protruding portions, the second diffusion layer includes plural second protruding portions, and at least a portion of side surfaces of the first protruding portions and the second protruding portions are formed to face each other.

Furthermore, in the above aspects, the third region may be provided so as to enclose the first region, and the second region is provided so as to enclose the third region.

According to a further aspect of the present invention, there is provided a method of fabricating a semiconductor device, the method comprising:

preparing a semiconductor substrate including a supporting substrate, a first insulating film formed on the supporting substrate, and a silicon film having a first region and a second region formed on the first insulating film, and a third region at least a portion of which is disposed between the first region and the second region;
forming a second insulating film on a surface of the silicon film;
forming a conductive film on the second insulating film;
etching the second insulating film and the conductive film to form a gate insulating film and a gate electrode, and to expose the first and the second regions in the silicon film;
forming a first resist pattern on at least a portion of the gate electrode and on the second region;
implanting impurities of a first conductive type in the first region by using the first resist pattern and the gate electrode as a mask to form a first diffusion layer in the first region;
forming a second resist pattern on at least a portion of the gate electrode and on the first region; and
implanting impurities of a second conductive type, which has a polarity opposite to that of the first conductive type, in the second region by using the second resist pattern and the gate electrode as a mask to form a second diffusion layer in the second region.

According to a still further aspect of the present invention, there is provided a method of fabricating a semiconductor device, the method comprising:

preparing a semiconductor substrate including a supporting substrate, a first insulating film formed on the supporting substrate, and a silicon film having a first region and a second region formed on the first insulating film, and a third region at least a portion of which is disposed between the first region and the second region;
forming a second insulating film on a surface of the silicon film;
forming a conductive film on the second insulating film;
etching the second insulating film and the conductive film to form a gate insulating film and a gate electrode, and to expose the first and the second regions in the silicon film;
implanting impurities of a first conductive type in the first and the second regions by using the gate electrode as a mask;
forming a third insulating film on the exposed silicon film and on the gate electrode;
etching back the third insulating film to form side walls at the side surfaces of the gate insulating film and the gate electrode;
forming a first resist pattern on at least a portion of the gate electrode and on the second region;
implanting impurities of a first conductive type in the first region by using the first resist pattern, the gate electrode, and the side walls as a mask to form a first diffusion layer in a portion of the first region;
forming a second resist pattern on at least a portion of the gate electrode and on the first region; and
implanting impurities of a second conductive type, which has a polarity opposite to that of the first conductive type, in the second region by using the second resist pattern, the gate electrode, and the side walls as a mask to form a second diffusion layer in a portion of the second region.

What is claimed is:

1. A semiconductor device comprising:
a semiconductor substrate including a supporting substrate, a first insulating film formed on the supporting substrate, and a silicon film having a first region and a second region formed on the first insulating film, and a third region at least a portion of which is disposed between the first region and the second region;
a first diffusion layer formed on the first region of the silicon film and having a first conductive type;
a second diffusion layer formed on the second region of the silicon film and containing impurities having a second conductive type, which has a polarity opposite to that of the first conductive type;
a second insulating film formed on the third region of the silicon film; and
a third insulating film formed on the second insulating film.

2. The semiconductor device of claim 1 further comprising:
side walls formed at both sides of the second and the third insulating films; and
a third diffusion layer formed in a region of the silicon film below the side walls.

3. The semiconductor device of claim 1, wherein the third region is provided in a lattice form so as to enclose each periphery of the first region and the second region, and the first diffusion layer and the second diffusion layer are plurally arranged so as to neighbor to each other via the third region.

4. The semiconductor device of claim 2, wherein the third region is provided in a lattice form so as to enclose each periphery of the first region and the second region, and the first diffusion layer and the second diffusion layer are plurally arranged so as to neighbor to each other via the third region.

5. The semiconductor device of claim 1, wherein the first diffusion layer includes plural first protruding portions, the second diffusion layer includes plural second protruding portions, and side surfaces of the first protruding portions and side surfaces of the second protruding portions are formed so that at least a portion thereof face each other.

6. The semiconductor device of claim 2, wherein the first diffusion layer includes plural first protruding portions, the second diffusion layer includes plural second protruding portions, and side surfaces of the first protruding portions and side surfaces of the second protruding portions are formed so that at least a portion thereof face each other.

7. The semiconductor device of claim 1, wherein the third region is provided so as to enclose the first region, and the second region is provided so as to enclose the third region.

8. The semiconductor device of claim 2, wherein the third region is provided so as to enclose the first region, and the second region is provided so as to enclose the third region.

9. A semiconductor device comprising:
a semiconductor substrate including a supporting substrate, a first insulating film formed on the supporting substrate, and a silicon film having a first region and a second region formed on the first insulating film, and a third region at least a portion of which is disposed between the first region and the second region;
a first diffusion layer formed on the first region of the silicon film and having a first conductive type;
a second diffusion layer formed on the second region of the silicon film and containing impurities having a second conductive type, which has a polarity opposite to that of the first conductive type;
a second insulating film formed on the third region of the silicon film; and
a gate electrode formed on the second insulating film.
